(19) United States
(12) Patent Application Publication
(10) Pub. No.: US 2003/0098060 A1
(43) Pub. Date: May 29, 2003

(54) Solar battery sealing film and method of manufacturing solar battery panel using the same

(76) Inventor: Naoki Yoshimi, Kitakatsuragi-gun (JP)

Correspondence Address: NIXON & VANDERHYE P.C., 8th Floor, 1100 North Glebe Rd., Arlington, VA, 22201-4714, US

(21) Appl. No.: 10/277,135

(22) Filed: Oct. 22, 2002

(30) Foreign Application Priority Data
Oct. 29, 2001 (JP) 2001-330997(P)
Aug. 30, 2002 (JP) 2002-254554(P)

(51) Int. Cl. H01L 31/00

(52) U.S. Cl. 136/251; 438/64; 136/256

(57) ABSTRACT

On a main surface of a solar battery sealing film formed of a transparent soft resin film including a linking agent for adhering and sealing the solar battery cells, a plurality of channels having the depth of at least 100 μm and reaching an end surface are formed by embossing. Thus, the time for manufacturing the solar battery panel can be reduced and, at the same time, generation of voids can be prevented.

### BACKGROUND OF THE INVENTION

1. Field of the Invention

The present invention relates to a solar battery sealing film and to a method of manufacturing a solar battery panel using the same. More specifically, the present invention relates to a solar battery sealing film formed of a transparent soft resin film including a linking agent with its surface embossed, and a method of manufacturing a solar battery panel using the same.

2. Description of the Background Art

Recently, solar power generation system for converting optical energy of sunlight to electric energy has come to be widely used as one means of power generation utilizing clean energy. A solar battery panel used in the photovoltaic power generation system generally has such a structure as shown in FIG. 6 in which a solar battery cell 13 as a photovoltaic element is sandwiched between sealing films 12A and 12B, and placed between a glass substrate 11 as a front side transparent protective member and a back film 14 as a back side protective member.

Such a solar battery panel is manufactured by stacking glass substrate 11, sealing film 12A, solar battery cell 13, sealing film 12B and back film 14 in this order and integrating these elements by adhering the sealing films through linking and curing, by applying heat and pressure. This process step is generally referred to as a laminate process, which is one of important process steps in manufacturing the solar battery panel. The laminate process will be described in detail in the following.

Referring to FIG. 6, in the laminate process, first, a plurality of solar battery cells 13 arranged in a matrix are connected in series or in parallel, using wires 15. Thereafter, the solar battery cells 13 connected to each other are sandwiched between sealing films 12A and 12B, and further between glass substrate 11 and back film 14 from above and from below, respectively. The stacked elements are heated and evacuated using a vacuum laminator. The heating process is to once melt sealing films 12A and 12B, and evacuation is to remove voids generated in the melt sealing films 12A and 12B.

After the sealing film is completely melted by the heating and evacuating process, these elements are pressed from above and from below. Evacuation is continued while pressing, and when voids are completely eliminated in sealing films 12A and 12B, heating process at a high temperature is further performed, so as to cure sealing films 12A and 12B. A press processing is performed to control thickness of the solar battery panel, and heating is to cause linking reaction of the linking agent included in sealing films 12A and 12B so as to cure sealing films 12A and 12B. Through the above described steps, a solar battery panel is manufactured in which solar battery cells 13 are held between glass substrate 11 and back film 14.

A transparent soft resin film processed to a film by extrusion, for example, is used as the solar battery sealing film. The film should be transparent in order to maintain high transmittance of sunlight, and it should be soft, so as to prevent any damage on the surface of solar battery cells through the laminating process. Further, the member as a film is used, because it is easier to handle as compared with general resin adhesive in the form of a paste, and it is easier to control thickness of the adhesive layer. Generally, a film containing ethylene-vinyl acetate copolymer (EVA) as a main component is used as the transparent soft resin film including linking agent.

Japanese Patent Laying-Open No. 2000-183388 discloses a conventional solar battery sealing film of this type. In the solar battery sealing film disclosed in this laid-open application, protruded portions 12a and recessed portions 12b are formed continuously and alternately on the main surface facing solar battery cell, of solar battery sealing film 12 having the thickness t. Here, level difference d between protruded portion 12a and recessed portion 12b is about 15 to about 50 μm. The recesses and protrusions are formed to improve melting adhesion property and pressure adhesion property in the laminate process, as well as to enhance cushioning effect when it is brought into contact with the solar battery cell.

One important problem encountered when a solar battery panel is manufactured is reduction in time necessary for the laminate process. In the laminate process as conventionally carried out, considerable time was necessary for heating and evacuating processes. In the heating process, when pressing is performed while heating is insufficient, not-yet melted portion of the sealing film may possibly cause local stress concentration at a surface of a solar battery cell, inducing damages to the cell. In the evacuating process, when linking and curing reaction proceeds while evacuation is insufficient, voids result in the solar battery panel, resulting in lower efficiency in power generation and lower reliability of the whole apparatus. Thus, sufficient heating and evacuation are essential. As a result, the time necessary for the laminate process increases, undesirably lowering production efficiency.

The technique disclosed in Japanese Patent Laying-Open No. 2000-183388 mentioned above has been developed to improve cushioning effect of the sealing film, in order to enable press processing even when sealing film is not yet melted. Generally, however, the thickness of the sealing film sealing the solar battery cell is about 400 to about 600 μm. Therefore, even when recesses and protrusions of about 15 to about 50 μm are provided, level difference of the recesses and protrusions with respect to the thickness of the sealing film is at most about 12.5%, and the cushioning property thereof is still considerably low. Therefore, in order to actually improve production yield, pressing must still be performed after the sealing film is completely melted, and the technique does not contribute to reduction in time of the laminate process. Further, even when recesses and protrusions of about 15 to about 50 μm are provided, evacuation property is the same as the conventional technique, and therefore, the disclosed technique does not contribute to reduction in time of evacuation, either.

### SUMMARY OF THE INVENTION

An object of the present invention is to provide a solar battery sealing film enabling reduction in time necessary for manufacturing a solar battery panel, preventing generation of voids and significantly reducing damages to the solar battery cell, and to provide a method of manufacturing a solar battery panel using the same.

The solar battery sealing film of the present invention is a transparent soft resin film including a linking agent, for sealing a photovoltaic element, and the sealing film has, on a main surface facing the photovoltaic element, channels having the depth of at least 100 μm and reaching an end surface of the film.

As channels having the depth of at least 100 μm are provided on the main surface facing the photovoltaic element of the solar battery sealing film reaching the end surface of the film, cushioning property can be improved. Therefore, it becomes possible to start pressing before the sealing film is melted. Further, during the press processing, air involved between the sealing film and the solar battery cell is forced out through the channels reaching the end surface as escape ways, and therefore, evacuation property improves. As a result, the time necessary for the heating process to melt the sealing film and necessary for evacuation for eliminating voids generated in the sealing film can significantly be reduced, and therefore, the time for laminate process can be reduced. Further, as the sealing film with channels is used, damages to the solar battery cell and generation of voids are prevented, and therefore production yield is improved.

In the solar battery sealing film in accordance with the present invention, it is preferred that the depth of the channel is at least 100 μm and at most 480 μm. In order to improve production yield and to reduce time for laminate process as described above, the depths of the channel from 100 μm to 480 μm is preferable. Channels having the depth in this range enable both good cushioning property and good evacuation property.

In the solar battery sealing film in accordance with the present invention, desirably, channels are formed reaching the end surface, also on the back surface opposite to the main surface. By providing channels having the depth of at least 100 μm not only on the main surface of the sealing film facing the solar battery cell but on the opposite side surface, cushioning property can further be improved. When channels are provided on both surfaces in this manner, the sealing film comes to have a wavy shape.

In the solar battery sealing film in accordance with the present invention, preferably, the channels formed on the back surface have the depth of at least 100 μm and at most 480 μm. By forming channels having the depths of 100 μm to 480 μm on the back surface of the solar battery sealing film, the cushioning property can further be improved. When channels are provided on both surfaces in this manner, the sealing film comes to have a wavy shape.

In the solar battery sealing film in accordance with the present invention, the transparent soft resin film is preferably formed of ethylene-vinyl acetate copolymer. When a transparent resin film containing ethylene-vinyl acetate copolymer as a main component is used, sufficient cushioning property is exhibited.

In the solar battery sealing film in accordance with the present invention, preferably, the channels are formed by press processing. By utilizing press processing, channels having the depth of at least 100 μm and reaching the side surface can easily be formed on one or both of the main surface and the back surface of the solar battery sealing film.

The method of manufacturing a solar battery panel in accordance with the present invention includes the step of forming, on a main surface facing a photovoltaic element of a solar battery sealing film formed of a transparent soft resin film including a linking agent for sealing the photovoltaic element, channels having the depth of at least 100 μm and reaching an end surface, and the step of adhering and sealing the photovoltaic element between a front surface side transparent protective member and a back surface side protective member by heat-pressing, using the solar battery sealing film.

When the solar battery panel is manufactured through the above described method, the press processing that has been conventionally performed after the solar battery sealing film is completely melted can be started before the sealing film is completely melted. Therefore, the time necessary for manufacturing the solar battery panel can significantly be reduced. This is because the cushioning property is improved, as channels having the depth of at least 100 μm are formed on that side of the solar battery sealing film which faces the photovoltaic element. Accordingly, the present manufacturing method ensures production yield comparable to or higher than the prior art.

In the method of manufacturing a solar battery panel in accordance with the present invention, preferably, the step of forming channels is realized by press processing. As press processing is utilized, channels having the depth of at least 100 μm and reaching the end surface can easily be formed on one or both of the main and back surfaces of the solar battery sealing film.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1A is a top view representing the shape of the sealing film in accordance with an embodiment of the present invention, and FIG. 1B is an end view thereof.

FIG. 2 is a schematic illustration representing the method of forming channels on the surface of the solar battery sealing film, in accordance with an embodiment of the present invention.

FIG. 3A is a top view representing Pattern Example 1 of the channels provided on the sealing film in accordance with an embodiment of the present invention, and FIG. 3B is a cross section taken along the line IIIB-IIIB of FIG. 3A.

FIG. 4A is a top view representing Pattern Example 2 of the channels formed on the sealing film in accordance with an embodiment of the present invention, and FIG. 4B is a cross section taken along the line IVB-IVB of FIG. 4A.

FIG. 5A is a top view representing Pattern Example 3 of the channels formed on the sealing film in accordance with an embodiment of the present invention, and FIG. 5B is a cross section taken along the line VB-VB of FIG. 5A.

FIG. 6 is an exploded perspective view representing the structure and manufacturing method of the solar battery panel.

FIG. 7 is an end view representing the shape of a conventional solar battery sealing film.

### DESCRIPTION OF THE PREFERRED EMBODIMENTS

An embodiment of the present invention will be described in the following with reference to the figures.

(Shape of Solar Battery Sealing Film)

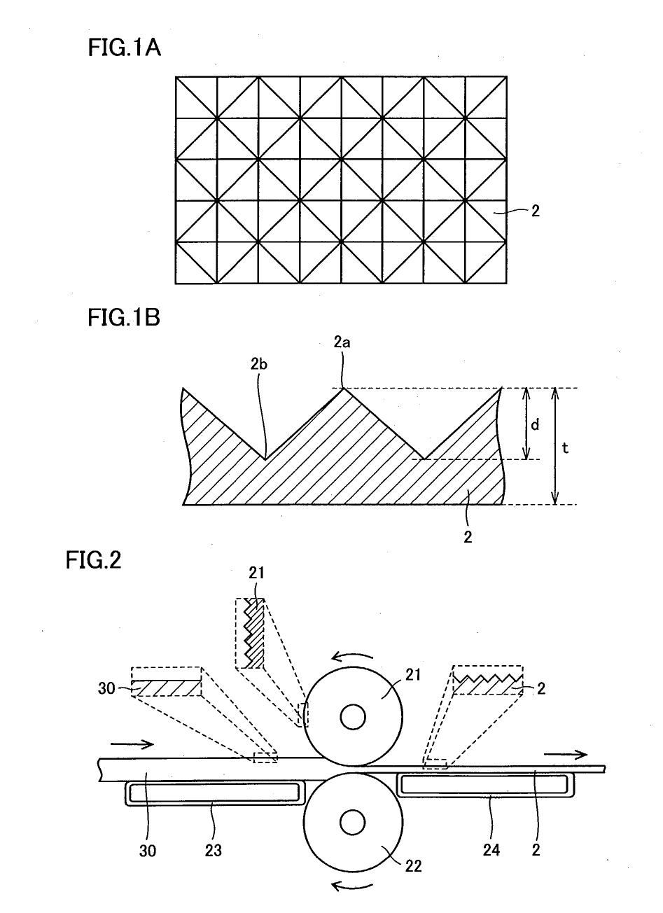

First, referring to FIGS. 1A and 1B, the shape of the solar battery sealing film in accordance with the present embodiment will be described. As shown in FIGS. 1A and 1B, the solar battery sealing film 2 is a sealing member in the form of a film, having the thickness t. On the main surface of solar battery sealing film 2 facing the solar battery cell, protruded portions 2a and recessed portions 2b are formed alternately and continuously, and these recessed portions and protruded portions 2a and 2b form channels, which are formed to reach an end surface of solar battery sealing film 2.

The depth d (level difference between the highest portion of protruded portion 2a and the deepest portion of recessed portion 2b) of the channel is at least 100 μnm. Generally, thickness t of a sealing film used as the solar battery sealing film is about 400 μm to about 600 μm. Therefore, the depth d of the channel with respect to the thickness t is about 20% or higher, and compared with the conventional sealing film, the cushioning property is significantly improved. Such solar battery sealing film 2 preferably is a sealing film formed by a transparent soft resin composition including a linking agent and, more preferably, contains EVA resin composition as the main component.

(Method of Manufacturing Solar Battery Panel)

First, referring to FIG. 2, the method of forming channels on the surface of the solar battery sealing film will be described. In the present embodiment, press processing is used as the method of forming channels on the surface of the solar battery sealing film. Here, “press processing” refers to emboss processing performed in the step of rolling during manufacturing of the solar battery sealing film, in which, using the roll having recesses and protrusions of a prescribed shape formed on the surface, an intermediate product for the solar battery sealing film is rolled and, at the same time, recesses and protrusions are formed on the surface of the solar battery sealing film. The details will be described in the following.

In the step of rolling, generally, rollers positioned along the up/down direction as shown in FIG. 2 are used. An intermediate product 30 of the solar battery sealing film is fed to the gap between an upper roll 21 and a lower roll 22 by a belt conveyer 23. Upper roll 21 and lower roll 22 are arranged spaced by a distance in accordance with the thickness of solar battery sealing film 2 to be manufactured. Therefore, the intermediate product 30 of solar battery sealing film is stretched thin to a desired thickness by upper and lower rolls 21 and 22, and fed out by belt conveyer 24.

Here, in the present embodiment, in order to form channels having the depth of at least 100 μm and reaching the end surface as described above on the main surface of solar battery sealing film 2, upper roll 21 having recesses and protrusions on which level difference is at least 100 μm formed on the surface is used. Thus, channels of the desired shape can be formed in a simple manner simultaneously with the rolling, on the main surface of solar battery sealing film 2.

The method of manufacturing the solar battery panel using the solar battery sealing film will be described in the following. The method of manufacturing the solar battery panel in accordance with the present embodiment is basically the same as the conventional method of manufacturing the solar battery panel. It is noted, however, that as the solar battery sealing film, the film having on its main surface channels with the depth of 100 μm or deeper and reaching the end surface formed through the above described press processing, is used.

In manufacturing the solar battery panel in accordance with the present embodiment, a glass substrate, the solar battery sealing film, solar battery cells, the solar battery sealing film and a back film are stacked in this order, and integrated by adhesion, through linking and curing of the sealing films by applying heat and pressure. By the laminate process described above, the solar battery panel is manufactured.

(Function Effects)

The solar battery sealing film having the structure as described with respect to the embodiment above has superior cushioning property and superior evacuation property, as compared with the prior art. The improvement in the cushioning property results from the fact that deep channels of 100 μm or deeper are provided on the surface, and improvement in the evacuation property results from the fact that the channels are formed to reach the end surface of the sealing film. Specifically, when the sealing film is pressed against the solar battery cell, the channels serve as escape ways of air, reducing involvement of the air. As a result, when the solar battery panel is manufactured using the sealing film, generation of defects caused by the damages to the solar battery cells can significantly be reduced, and degradation of power generation or reliability resulting from voids generated in the sealing film can be prevented.

Further, as the laminate process is performed using the solar battery sealing film having the above described structure, it becomes possible to start press processing before the sealing film melts completely.

Further, evacuation process can be completed in a time period shorter than in the prior art because of improved evacuation property, and therefore, the time for the laminate process can significantly be reduced. As a result, production efficiency is improved and manufacturing cost is reduced.

The channels may be provided only on the main surface facing the solar battery cells, of the solar battery sealing film, or the channels may be provided both on the main surface and the back surface. When the channels are to be formed only on the main surface of the sealing film, the depth of the channels should preferably be about 100 μm to about 480 μm. When the channels are to be formed on both surfaces, preferably, the depth of the channels on the back surface should also be about 100 μm to about 480 μm. When channels are formed both on the main surface and the back surface, the resulting sealing film comes to have a wavy shape. In order to prepare the solar battery sealing film of such a shape, the upper and lower rolls used for the press process described above are implemented by rolls having recesses and protrusions with the level difference of 100 μm to 480 μm on its surface. Thus, it becomes possible to emboss both surfaces of the solar battery sealing film simultaneously with rolling, and the solar battery sealing film having the wavy shape as described above can be manufactured.

### PATTERN EXAMPLES OF THE CHANNEL

In the following, a few pattern examples of the channels provided on the surface of the solar battery sealing film in accordance with an embodiment will be described.

### Pattern Example 1

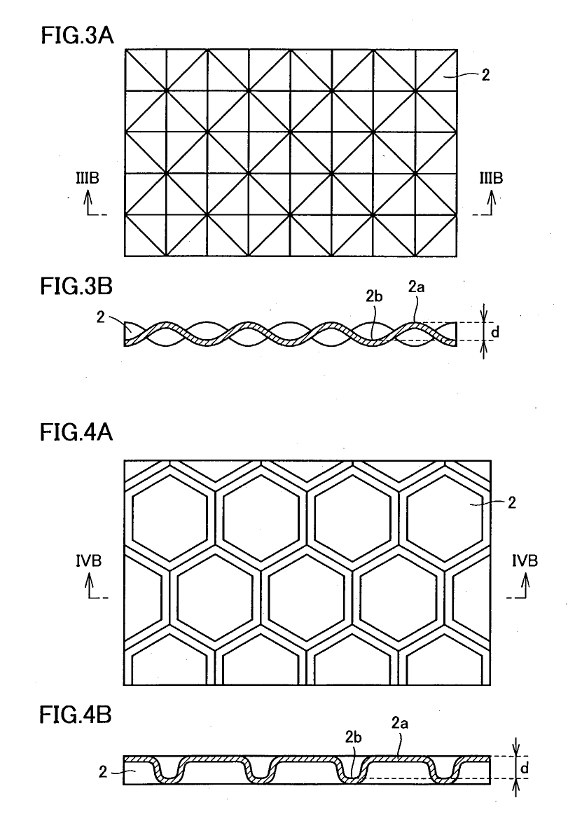

In the pattern example of channels shown in FIGS. 3A and 3B, recesses and protrusions are formed in a lattice shape, on both surfaces of the sealing film 2. More specifically, the surface of sealing film 2 is sectioned such that rhombus of the same size are arranged continuously side by side with one side shared with each other, with the central point of each rhombus being the top point of protruded portion 2a and an end point of the rhombus being the bottom point of recessed portion 2b. By such a pattern of channels, channels reaching the end surface of the sealing film are formed. In the following, this pattern of channels will be referred to as “diamond lattice pattern”.

### Pattern Example 2

In the pattern example of channels shown in FIGS. 4A and 4B, again, recesses and protrusions are formed on both surfaces of the sealing film. In this pattern example, emboss processing is performed such that the surface of the sealing film is sectioned such that hexagons of the same size are arranged continuously side by side with one side shared with each other, with the inside of each hexagon being the protruded portion 2a and the side being the recessed portion 2b. By this channel pattern, channels reaching the end surface of the sealing film will be formed in continuous hexagons. In the following, this channel pattern will be referred to as “hexagonal pattern”.

### Pattern Example 3

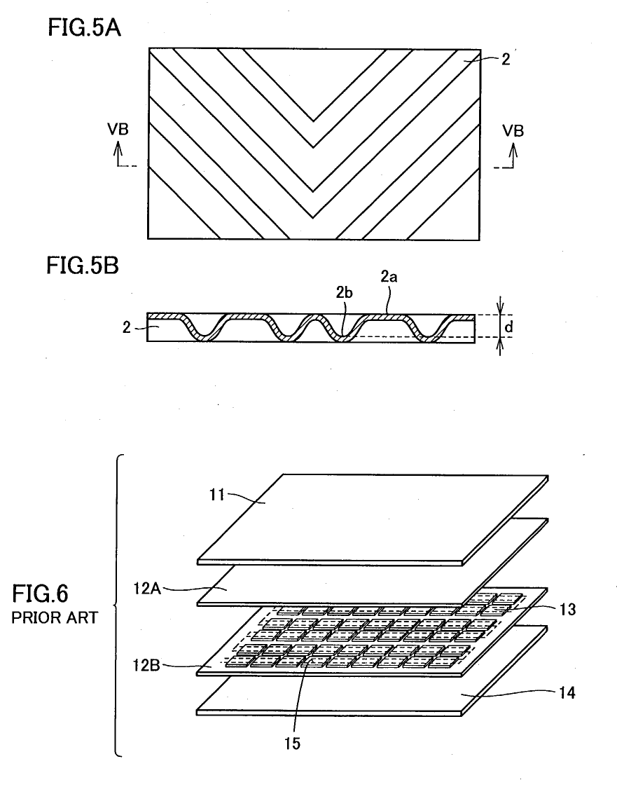

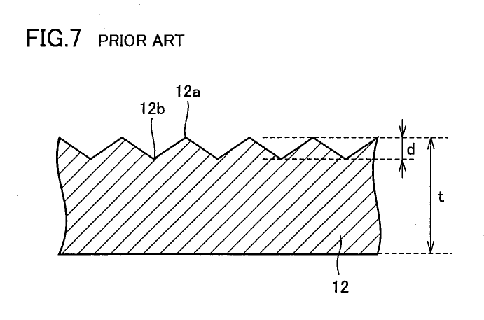

In the pattern example of channels shown in FIGS. 5A and 5B, again, recesses and protrusions are formed on both surfaces of the sealing film. In the present pattern example, channels are formed in V-shapes when viewed from above, on the surface of the sealing film. The V-shaped portions are recessed portions 2b and other portions are protruded portions 2a. By this channel pattern, V-shape channels are formed to the end surface of the sealing film. In the following, this pattern will be referred to as “V-shape pattern”.

### EXAMPLES

Examples using channel patterns 1 to 3 will be described in the following. In each of Examples 1 to 8, 50 samples were made using EVA film as the transparent soft resin composition, with depths and patterns of the channel changed variously. The samples each had the size of 800 mm×1200 mm and the thickness of 600 μm, and had such depths and patterns of channels as shown in Table 1 below.

The solar battery panels using these samples were manufactured with the heating temperature of 100 to 150° C., evacuation time of 4 minutes, press pressure of 1 atm (=1.01325×10⁵N/m²) and press time of 10 minutes. In every sample, press processing was started before the sealing film was completely melted. Number of defective samples resulting from generation of voids and number of defective samples resulting from damages to the solar battery cells as a result of manufacturing the solar battery panels in this manner are as shown in Table 1.

TABLE 1

| | Examples | | | | | | | |
|---|---|---|---|---|---|---|---|---|
| | 1 | 2 | 3 | 4 | 5 | 6 | 7 | 8 |
| Embossed | diamond | diamond | diamond | diamond | diamond | continuous | hexagonal | diamond |
| channel | lattice- | lattice- | lattice- | lattice- | lattice- | V-shape | | lattice- |
| shape | shape | shape | shape | shape | shape | | | shape |
| Channels | both | both | both | both | both sides | both sides | both sides | one side |
| formed on | sides | sides | sides | sides | | | | |
| Channel | 480 | 360 | 240 | 120 | 100 | 480 | 480 | 480 |
| depth (μm) | | | | | | | | |
| Number of | 0 | 0 | 0 | 0 | 0 | 0 | 0 | 0 |
| solar battery | | | | | | | | |
| panels with | | | | | | | | |
| voids | | | | | | | | |
| Number of | 0 | 0 | 0 | 0 | 0 | 0 | 0 | 0 |
| solar battery | | | | | | | | |
| panels with | | | | | | | | |
| damages to | | | | | | | | |
| solar cells | | | | | | | | |
| Evacuation | 4 | 4 | 4 | 4 | 4 | 4 | 4 | 4 |
| time | | | | | | | | |

As can be seen from Table 1, according to the embodiment, there was no solar battery panel in which generation of voids was observed. Further, there was no solar battery panel in which damages to the solar battery cells were observed. Therefore, it was confirmed that by forming channels having the depth of at least 100 μm and reaching the end surface on the main surface of the sealing film, the time necessary for the laminate process could be reduced and production yield could significantly be improved.

### COMPARATIVE EXAMPLES

For comparison with the examples above, Comparative Examples 1 to 4 will be described in the following. In each of Comparative Examples 1 to 4, 50 samples were formed using EVA film as the transparent soft resin composition as in Examples above, with channel depths and patterns changed variously. The samples each had the size of 800 mm×1200 mm and the thickness of 600 μm, as above. In Comparative Examples 1 and 2, diamond lattice pattern were formed by embossing on the surface of the sealing film. The depths, however, was in each pattern smaller than 100 μm. Comparative Examples 3 and 4 are not subjected to embossing.

The solar battery panels were manufactured using these comparative samples, with the heating temperature of 100 to 150° C., evacuation time of 4 minutes, press pressure of 1 atm (=1.01325×10⁵N/m²) and the press time of 10 minutes. In Comparative Example 4 only, the evacuation time was set to 8 minutes. Press processing was started before the sealing film was completely melted. The number of detective samples resulting from generation of voids and the number of defective samples resulting from damages to the solar battery cells of the result of manufacturing of the solar battery panels in this manner are as shown in Table 2.

TABLE 2

| | Comparative Example | | | |
|---|---|---|---|---|
| | 1 | 2 | 3 | 4 |
| Embossed channel | diamond lattice- | diamond lattice- | — | — |
| shape | shape | shape | | |
| Channels formed on | both surfaces | both surfaces | — | — |
| Channel depth (μm) | 80 | 60 | 0 | 0 |
| Number of solar | 4 | 6 | 15 | 0 |
| battery panels with | | | | |
| voids | | | | |
| Number of solar | 3 | 3 | 4 | 1 |
| battery panels with | | | | |
| damages to solar cells | | | | |
| Evacuation time | 4 | 4 | 4 | 8 |

As can be seen from Table 2, even when channels reaching the end surface are provided on the surface of the sealing film, voids are generated and solar battery cells are damaged at a prescribed ratio, when the depths of the channel is smaller than 100 μm. When channels are not at all formed, the defective ratio increases significantly, resulting in very low production yield. When the sealing film not provided with such channels is used, it is possible to reduce generation of voids by making longer the evacuation time.

In that case, however, damages to the solar battery cells cannot perfectly be prevented.

As described above, it was confirmed that by the present invention, the time necessary for the entire laminate process could be reduced for the first time, and that generation of voids and damages to the solar battery cells could be prevented, leading to improved production yield.

Though an EVA resin film including a linking agent has been described as the solar battery sealing film in the embodiment above, it is not limiting, and the channel patterns to be formed on the surface are not limited to the three patterns described above. The thickness of the solar battery sealing film is not specifically limited, either.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. A solar battery sealing film for sealing photovoltaic element, formed of a transparent soft resin film including a linking agent, and having, on a main surface facing said photovoltaic element, a channel having depth of at least 100 μm and reaching an end surface.

2. The solar battery sealing film according to claim 1, wherein said depth of the channel is at least 100 μm and at most 480 μm.

3. The solar battery sealing film according to claim 1, wherein a channel having depth of at least 100 μm and reaching an end surface is formed on a back surface opposite to said main surface.

4. The solar battery sealing film according to claim 3, wherein said depth of the channel formed on the back surface is at least 100 μm and at most 480 μm.

5. The solar battery sealing film according to claim 1, formed of an ethylene-vinyl acetate copolymer.

6. The solar battery sealing film according to claim 1, wherein said channel is formed by press processing.

7. A method of manufacturing a solar battery panel, comprising the steps of
forming, on a main surface of a solar battery sealing film formed of a transparent soft resin film including a linking agent for sealing a photovoltaic element, said main surface facing said photovoltaic element, a channel having depth of at least 100 μm and reaching an end surface; and
adhering and sealing said photovoltaic element between a front side transparent protective member and a back side protective member by applying heat and pressure, using said solar battery sealing film.

8. The method of manufacturing a solar battery panel according to claim 7, wherein
said step of forming said channel includes press processing.
